(19) United States
(12) Patent Application Publication
(10) Pub. No.: US 2026/0033295 A1
(43) Pub. Date: Jan. 29, 2026

(54) OPTICAL WAFER MONITORING

(71) Applicant: Tokyo Electron Limited, Tokyo (JP)

(72) Inventors: Scott Lefevre, Albany, NY (US); Henry Puretz, Albany, NY (US); Brendan Bathrick, Malta, NY (US); Joshua Baillargeon, Albany, NY (US)

(21) Appl. No.: 18/787,827

(22) Filed: Jul. 29, 2024

(51) Int. Cl. H01L 21/66; H01L 21/67; H01L 21/68; H01L 21/687

(52) U.S. Cl. CPC H10P 74/238; H10P 72/0606; H10P 72/53; H10P 72/7612

(57) ABSTRACT

A method for monitoring a dechucking of a wafer includes illuminating, using light generated from a light source, the wafer disposed on a wafer holder in a processing chamber. The method further includes lifting, using pins disposed in the wafer holder, the wafer, and during the lifting, collecting a portion of the light at a light detector. And the method further includes, based on the collected portion of the light, determining whether to continue the lifting to complete the dechucking.

### TECHNICAL FIELD

The present invention relates generally to a system and method for wafer monitoring, and, in particular embodiments, to a system and method for monitoring a wafer during a dechucking process.

### BACKGROUND

In the manufacture of semiconductor devices, wafers undergo a variety of processes that include deposition, etching, lithography, and ion implantation. These steps are performed while the wafer is held in place by a chuck within a processing chamber. At certain stages of the manufacturing process, in particular after completion of vacuum-based or plasma-based activities, the wafer is removed from the chuck, a process known as dechucking.

### SUMMARY

In accordance with an embodiment of this disclosure, a method for monitoring a dechucking of a wafer includes illuminating, using light generated from a light source, the wafer disposed on a wafer holder in a processing chamber. The method further includes lifting, using pins disposed in the wafer holder, the wafer, and during the lifting, collecting a portion of the light at a light detector. And the method further includes, based on the collected portion of the light, determining whether to continue the lifting to complete the dechucking.

In accordance with another embodiment of this disclosure, a method for monitoring a dechucking of a wafer includes having the wafer disposed on a wafer holder of a processing chamber, and illuminating the processing chamber. And the method further includes lifting, using pins disposed in the wafer holder, the wafer from the wafer holder to a predetermined distance above the wafer holder, and during the lifting performing a cyclic process. One cycle of the cyclic process includes obtaining an image corresponding to a location of the wafer during the lifting. One cycle of the cyclic process further includes, based on the image, performing one of the following steps: continuing the lifting of the wafer, modifying a parameter of the lifting, or lowering the wafer back on to the wafer holder to restart the lifting of the wafer.

And in accordance with yet another embodiment of this disclosure, a system for monitoring a dechucking of a wafer includes a wafer holder disposed in a processing chamber, the wafer holder including pins. The system further includes a light source optically coupled to the processing chamber, and a light detector optically coupled to the processing chamber. And the system further includes a processor coupled to the light detector, a memory, and a controller, the controller coupled to the light detector, the pins, the light source, and the memory storing instructions to be executed in the controller. The instructions when executed cause the controller to illuminate, using light generated from the light source, the wafer disposed on the wafer holder in the processing chamber. The instructions when executed further cause the controller to lift, using the pins disposed in the wafer holder, the wafer, and during the lifting, collect a portion of the light at the light detector. And the instructions when executed further cause the controller to, based on the collected portion of the light, determine whether to continue the lifting to complete the dechucking using the processor.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a wafer monitoring system in accordance with an embodiment;

FIG. 2 is a plot illustrating pin parameters during a dechucking process in accordance with an embodiment;

FIGS. 3A-3C illustrate various steps of a dechucking process in accordance with an embodiment;

FIGS. 4A-4C illustrate various steps of a dechucking process in accordance with an embodiment;

FIGS. 5A-5C illustrate various steps of a dechucking process in accordance with an embodiment;

FIG. 6 is a flowchart describing a method of monitoring the dechucking of a wafer in accordance with an embodiment; and

FIG. 7 is a flowchart describing a method of monitoring the dechucking of a wafer in accordance with an embodiment.

### DETAILED DESCRIPTION OF ILLUSTRATIVE EMBODIMENTS

Traditional wafer dechuck mechanisms rely heavily on mechanical or electrostatic ability to release the wafer. However, these conventional methods are prone to generating mechanical stress and particulate contamination, potentially inducing defects that degrade the quality and performance of the final semiconductor devices. Moreover, variations in processing conditions can lead to wafer sticking, where wafers become adhered to the chuck more firmly than intended, thus increasing the risk of damage when attempting to dechuck.

Current detection systems for wafer condition and anomalies during dechucking are limited. They typically involve post-process inspections that only detect faults after the wafer has been removed from the chuck. Such methods result in significant delays in detecting defects and often result in rework or scrapping of the affected wafers. Other detection systems monitor parameters of pins used to dechuck wafers, but may not be able to detect all forms of dechucking or lifting movements which may damage, break, or even drop wafers during dechucking.

An improved system that can provide real-time optical monitoring and feedback during the dechuck process to detect and prevent wafer damage as it occurs may be beneficial. More accurate and immediate detection of potential issues can result in significantly reduced wafer breakage, and a higher yield of usable semiconductor devices.

Thus, a real-time optical wafer monitoring system that can provide immediate visual confirmation of wafer condition and facilitate precise control during dechucking would be highly beneficial. Such a system would be non-invasive and capable of integration within existing processing chamber configurations without substantially altering process flows or chamber ergonomics.

This disclosure describes wafer monitoring systems and methods which may be used to monitor dechucking processes and prevent wafer breaking events from occurring. The systems and methods of this disclosure accomplish this by using a real-time optical monitoring system. By including the use of a light source configured to illuminate the inside of a processing chamber during the dechucking of a wafer from a wafer holder, and a light detector configured to record images or video in real-time of the inside of the processing chamber during the dechucking, the systems and methods of this disclosure may recognize and prevent more wafer breaking phenomena than conventional systems and methods. Further, the wafer monitoring systems and methods of this disclosure may also use the monitoring of pin parameters of the pins used during the dechucking process in combination with the real-time optical capabilities to further optimize wafer dechucking processes and prevent breaking the wafers. As a result, the wafer monitoring systems and methods of this disclosure can prevent tool breaking events which may occur when the wafers break, and thus avoid long down times for tool repair.

The wafer monitoring systems and methods of this disclosure may prevent more forms of wafer breaking events from occurring during dechucking processes than conventional systems and methods. By preventing wafer breakage, the wafer monitoring systems and methods of this disclosure may reduce fabrication costs (such as losing a wafer that had finished processing, but breaks during dechucking), and may prevent long tool down times from tool repair caused by wafer breaks. Further, the fabrication up time may be maximized and the damage to products may be minimized through the optimization capabilities of the real-time optical wafer monitoring systems and methods of this disclosure. Additionally, not losing wafers due to wafer breakage in dechucking processes also improves fabrication efficiency.

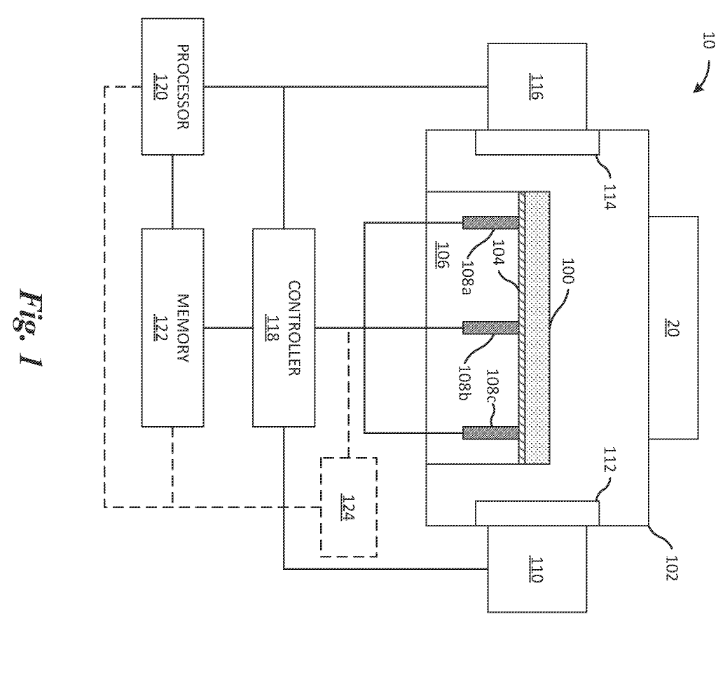

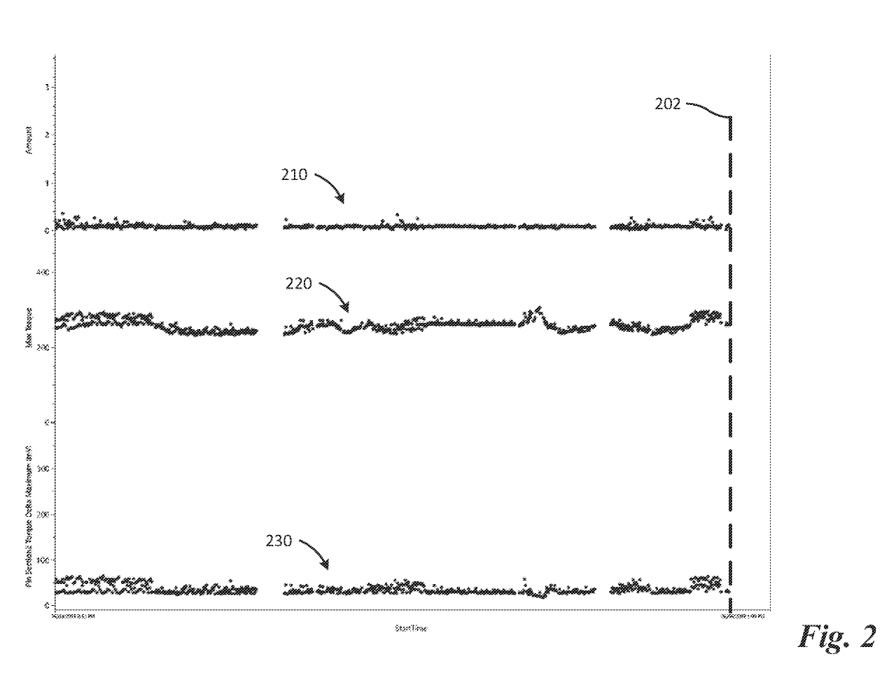

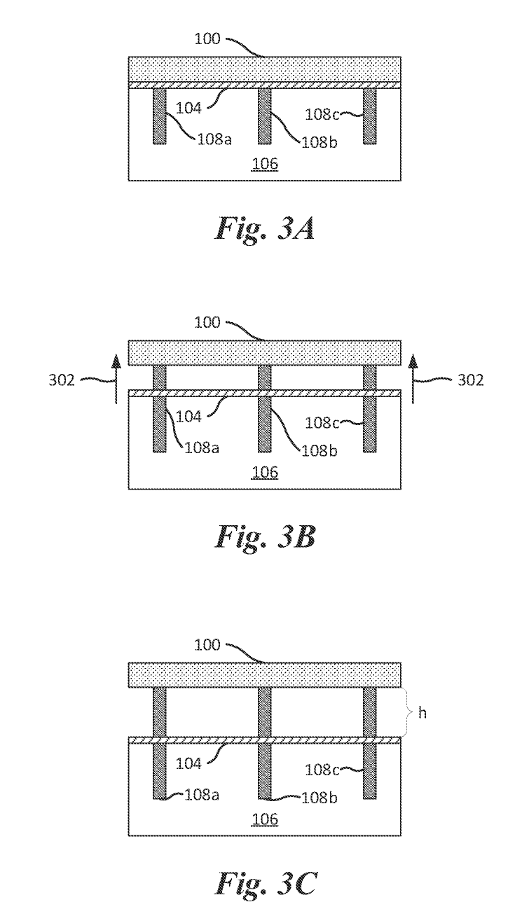

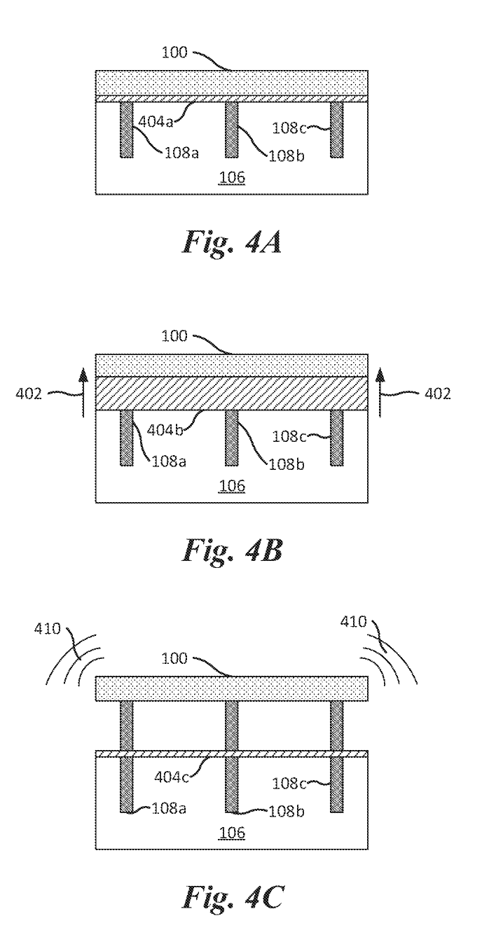

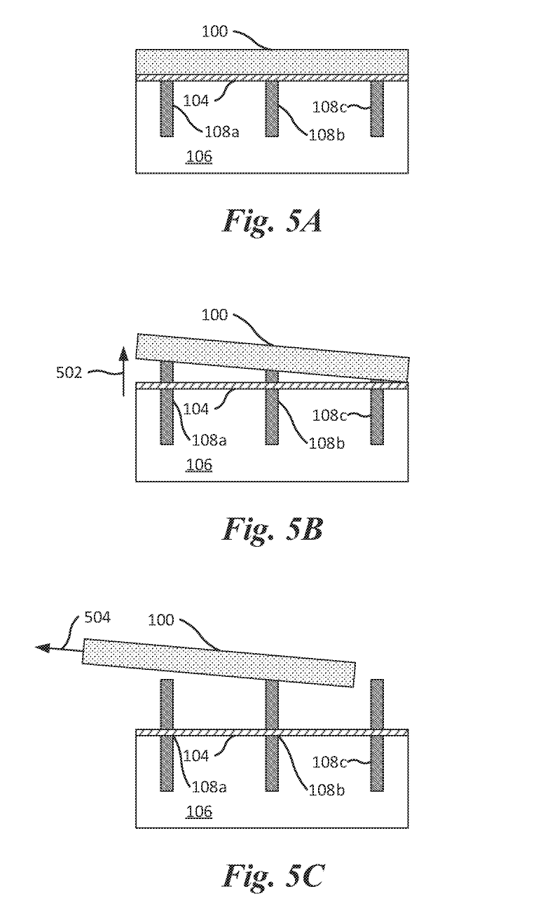

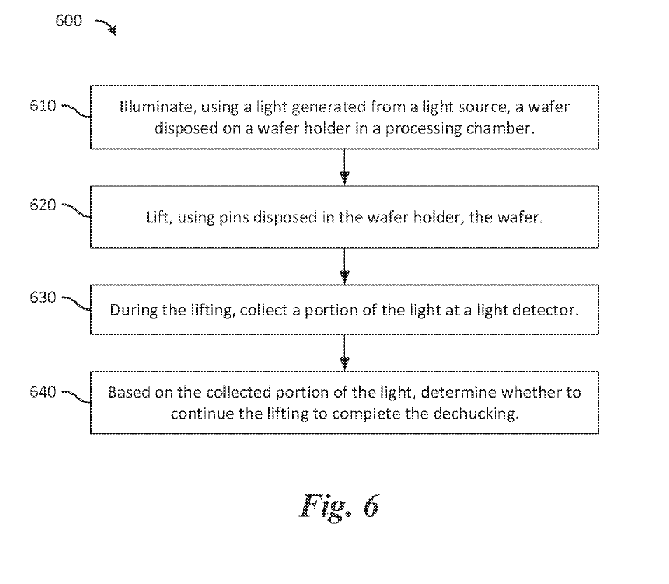

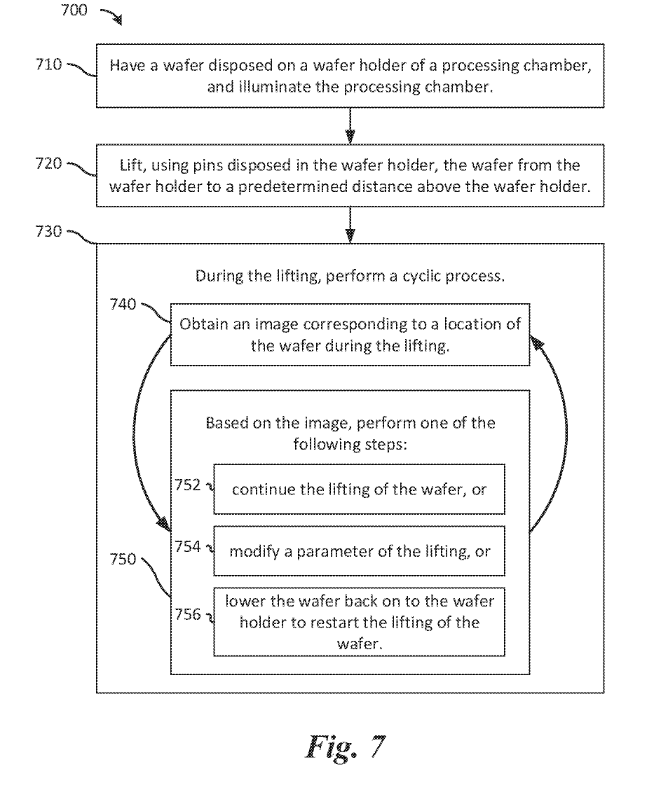

Embodiments provided below describe various methods, apparatuses, and systems of monitoring a wafer, and in particular, to methods, apparatuses, and systems that use a light detector to monitor a wafer during a dechucking process in real-time. The following description describes the embodiments. FIG. 1 is used to describe an example wafer monitoring system. FIG. 2 is used to illustrate how conventional pin monitoring parameters may not indicate wafer breakage before the wafer breaks. An example standard lifting motion of the wafer during a dechucking process which may be used to detect lifting movement variations in subsequent wafer dechuckings is described using FIGS. 3A-3C. An example lifting movement which may cause wafer breakage or the wafer falling that the wafer monitoring systems and methods of this disclosure may prevent is described using FIGS. 4A-4C. Another example lifting movement which may cause wafer breakage or the wafer falling that the wafer monitoring systems and methods of this disclosure may prevent is described using FIGS. 5A-5C. And FIGS. 6-7 are used to describe two other embodiment methods of monitoring a wafer in real-time of this disclosure.

FIG. 1 illustrates a block diagram of a wafer monitoring system 10 capable of monitoring the dechucking of a wafer 100 in accordance with an embodiment. The wafer monitoring system 10 comprises a processing tool 20 coupled to a processing chamber 102 which may be used to process the wafer 100. The processing chamber 102 comprises a wafer holder 106, an incident window 112, and a collection window 114. The wafer holder 106 comprises a seal band 104, and pins 108a-c. In FIG. 1, the wafer 100 is disposed on the wafer holder 106 with pins 108a-c retracted and a seal band 104 sealing the edges of the wafer 100 to the wafer holder 106.

The wafer monitoring system 10 further comprises a light source 110 optically coupled to the incident window 112, and a light detector 116 optically coupled to the collection window 114. Additionally, the wafer monitoring system 10 comprises a controller 118 coupled to pins 108a-c, the light source 110, the light detector 116, a processor 120, and a memory 122. In the embodiment illustrated in FIG. 1, the processor 120 is coupled to the memory 122, the controller 118, and the light detector 116. In various embodiments, the wafer monitoring system 10 may further comprise a torque monitor 124 coupled to pins 108a-c, the processor 120, and the memory 122.

Wafer 100 may be any suitable form of wafer processed in the processing chamber 102 using the processing tool 20 of the wafer monitoring system 10. For example, wafer 100 may be any suitable substrate, such as an insulating, conducting, or semiconducting substrate with one or more layers disposed thereon. One example category of possible wafers would be one of the many types of semiconductor wafer (silicon, silicon-on-insulator, germanium, gallium arsenide, etc.). The wafer holder 106 may be any device suitable for holding the wafer 100 during processing using the processing tool 20. In various embodiments, the wafer holder 106 may be an electrostatic chuck, a mechanical chuck, or a vacuum chuck.

Still referring to FIG. 1, the wafer holder 106 comprises the seal band 104 and the three pins 108a-c which may be used in a dechucking process to lift the wafer 100 from the wafer holder 106. In other embodiments, the wafer holder 106 may comprise more than three pins, such as embodiments with four, or five pins. And the pins 108a-c may be of a suitable material for lifting the wafer 100 from the wafer holder 106 in a dechucking process (or lifting movement), such as stainless steel, Al₂O₃ (sapphire), polyetheretherketone (PEEK), or a ceramic material. The seal band 104 may be used to form a seal around the outer edge of the wafer 100 such that a backside of the wafer 100 contacts the wafer holder 100. For example, in an embodiment where the wafer holder 106 comprises an electrostatic chuck, the wafer 100 may be sealed around the outer edge of the wafer 100 with the seal band 104 such that the backside of the wafer makes contact with the wafer holder 106 and may be electrostatically biased (such as through an electrical coupling to a power supply) to hold the wafer 100 in place during processing. The seal band 104 may be any band suitable for forming the seal around the outer edge of the wafer 100, such as a material that exhibits low out-gassing, resists erosion in chemically aggressive environments, comprises ultrapure material sets, and is capable of withstanding low-to-high temperatures. Further, the material of the seal band 104 may have the proper hardness and proper compression set for compliance, and proper permeability for reliable sealing. For example, the material of the seal band 104 may be an elastomer, such as fluorinated elastomers. And fluorinated elastomers may comprise fluoroelastomers, perfluoroelastomers, and hybrid fluoropolymers. In some embodiments, the seal band 104 may comprise Al₂O₃.

The incident window 112 and the collection window 114 may be of any suitable material for enabling the processing chamber 102 to be illuminated by the light source 110 and enabling the light detector 116 to collect light from within the processing chamber 102. For example, in various embodiments, the incident window 112 and the collection window 114 may be quartz, sapphire, alumina, borosilicate glass, MgF₂, CaF₂, various types of glass, or some form of suitable polymer material such as polyetheretherketone (PEEK). In various embodiments, the incident window 112 and the collection window 114 may comprise suitable materials transparent to the deep ultraviolet (DUC), ultraviolet (UV), visible (VIS), and infrared (IR) portions of the electromagnetic spectrum.

In various embodiments, the materials of the incident window 112 and the collection window 114 may comprise different materials. And in various embodiments, the material of the incident window 112 and the collection window 114 may be the same material. Further, the incident window 112 and the collection window 114 may comprise materials optimized for the wavelength of light from the light source 110 used to illuminate the processing chamber 102. In some embodiments, the material of the collection window 114 may be optimized for the collection of light (recording of video) by the light detector 116. In various embodiments, it may be beneficial for the incident window 112 and the collection window 114 to have a shade or covering which may cover the windows during the processing of the wafer 100, and which may be opened for the real-time monitoring of the wafer 100 after processing is complete and the dechucking process commences.

Though the embodiment wafer monitoring system 10 illustrated in FIG. 1 comprises the incident window 112 and the collection window 114, other embodiments may comprise a single window. In the embodiments comprising a single window into the processing chamber, the light source and the light detector may both be optically coupled to the same window. In various embodiments, the wafer monitoring system may comprise an incident window and a collection window, but not have the windows disposed opposite of each other. For example, in a similar embodiment, the incident window may be disposed on a sidewall and face a direction 90˚ offset from the direction the collection window faces. In some embodiments, the wafer monitoring system may be configured in a normal incidence for the light emitted by the light source into the processing chamber, and comprise the light detector optically coupled to a window disposed on a sidewall of the processing chamber.

The processing chamber 102 may be any suitable processing chamber for the processing tool 20 being used to fabricate the wafer 100. For example, in an embodiment where the processing tool 20 is an etching tool (such as a plasma tool), the processing chamber 102 may be a plasma etch chamber. In other embodiments, the processing chamber 102 may be a deposition tool, and the processing chamber 102 may be a deposition chamber.

The light source 110 may be any device suitable for illuminating the inside of the processing chamber 102 at appropriate wavelengths to be detected by the light detector 116. For example, the light source 110 may be an LED bulb that emits light in the visible spectrum. In various other embodiments, the light source 110 may be narrow-band or broad-band. In various embodiments, the light source 110 may be continuous wave (CW), or a pulsed light source, and may be capable of emitting light comprising light wavelength ranges in the deep ultraviolet (DUV), ultraviolet (UV), visible (VIS), and infrared (IR) portions of the electromagnetic spectrum. Further, the light source 110 may comprise various incandescent and gas discharge light sources, flash lamps, LEDs, lasers, laser-driven plasma light sources (LDLS), etcetera. The light detector 116 may be any device suitable for collecting the light emitted by the light source 110 to illuminate the processing chamber 102, and which may be configured to monitor the dechucking process in real-time. For example, the light detector 116 may be a video camera, or some other form of optical recording device. In some embodiments, the light detector 116 may be a CCD camera configured to capture images of the inside of the processing chamber 102 at specific elapsed times of the dechucking process or at specific heights reached by the wafer 100 over the wafer holder 106. In various embodiments, the light detector 116 may be an array detector, such as a charge-coupled device (CCD), a charge-injection device (CID), a CMOS device, a photodiode, or combinations thereof to capture a particular spectrum of interest. In some embodiments, the light detector 116 may further comprise filters, such as low, high, and bandpass filters. For example, acousto-optic or Fabry-Perot, or more generally, interferometers or rotatable etalons or gratings may be used.

The memory 122 may be any device suitable for storing instructions and/or data to be used and/or executed by the controller 118 and/or the processor 120 to implement the wafer monitoring methods of this disclosure. The controller 118 may be any device suitable for controlling the wafer monitoring system 10 for implementing the wafer monitoring methods of this disclosure. The processor 120 may be any device suitable for processing the data from the light detector 116 and overwriting instructions stored in the memory 122 for controlling the wafer monitoring system 10. In some embodiments, the processor 120 may also process the information received from the torque monitor 124 in tandem with the information from the light detector 116 to optimize the ability for the wafer monitoring system 10 of this disclosure to prevent wafer breakage during dechucking processes. The torque monitor 124 may be any device suitable for monitoring pin parameters of the pins 108a-c during the dechucking process. For example, the torque monitor 124 may be used to monitor the torques of the pins 108a-c and the transfer navigation system (TNS) of the pins 108a-c, which measures the pre and post processing position of a wafer and may be capable of detecting absolute wafer movement from the processing.

In various embodiments the memory 122 may store instructions to be executed by the controller 118 and information from the light detector 116, the processor 120, and the torque monitor 124. The instructions stored in the memory 122, when executed by the controller 118 may cause the controller 118 to implement the wafer monitoring methods of this disclosure. For example, the controller 118 may be used to implement the wafer monitoring methods described in the flowcharts of FIGS. 6-7. In various embodiments, the processor 120 may be some form of computer, or a field programmable gate assembly (FPGA). For example, the processor 120 may be a digital or analog-based system, such as von Neumann and non-von Neumann architectures. The controller 118 may be an application specific integrated circuit (ASIC) specific to the wafer monitoring system 10 of FIG. 1. In various embodiments, the memory 122 may be some form of volatile memory, such as programmable read-only memory (PROM). In other embodiments, the memory 122 may be some form of removable storage, or a storage drive, such as solid state drives (SSDs) or hard disk drives (HDDs).

The controller 118 may instruct the light source 110 to illuminate the processing chamber 102 and then start the pins 108a-c in a lifting motion to lift the wafer 100 from the wafer holder 106. During the lifting, the controller 118 may control the light detector 116 to capture images at various points in time of the dechucking process (lifting). The processor 120 may be used to process the images recorded by the light detector 116 in real-time to monitor for wafer breakage indications or wafer falling scenarios which may occur during the dechucking process. Further, in some embodiments, the processor 120 may also incorporate the information from the torque monitor 124 to improve the ability for the processor 120 to recognize potential wafer breakage events or the wafer 100 falling in the processing chamber 102 (which may also break the wafer 100).

Based on the processing of the real-time images captured by the light detector 116 and processed in the processor 120, the processor 120 may modify pin parameters for the lifting (or dechucking process) and overwrite the instructions stored in the memory 122 with the modified lifting parameters. Further, the processor 120 may, in response to determining a wafer breakage event is about to occur, generate a control signal to stop the lifting by the controller 118 before the wafer 100 breaks and modify the lifting parameters. Some forms of lifting motion variation detected by the processor 120 which may lead to wafer breakage may be prevented by lowering the wafer 100 back onto the wafer holder 106 and restarting the lifting (dechucking process) without modifying the lifting parameters.

The controller 118 may then read the modified instructions in the memory 122 and implement them to continue the dechucking process until the wafer 100 reaches a preconfigured height above the wafer holder 106 to complete the dechucking. Example lifting parameters which may be modified by the processor 120 comprise a lift rate, pin pressures, pin timing, and raising or lowering. In various other embodiments, the wafer monitoring system 10 may use the processing capabilities of the controller 118 rather than a separate processor 120 to process the monitoring information from the light detector 116 and the torque monitor 124.

In some embodiments, the determination by the processor 120 may be based on monitoring the light intensity of the captured images and comparing them to a control stored in the memory 122. In various embodiments, the determination by the processor 120 may be comparing a video recorded by the light detector 116 in real-time to a control video stored in the memory 122 of a good dechucking process in order to detect variations in the lifting motions of the wafer during the dechucking. Example lifting motions are described using FIGS. 3A-3C, FIGS. 4A-4C, and FIGS. 5A-5C below.

The real-time optical monitoring capabilities of the light detector 116 of the embodiments of this disclosure may detect (and subsequently prevent) more wafer breakage events or wafer falling events during the dechucking process than conventional systems and methods that only monitor pin parameters. Certain wafer breakage events or wafer falling scenarios may not be noticeable in the pin parameters of conventional systems. The lack of indication of wafer breakage or of a wafer falling during a dechucking process in pin parameters monitored by conventional wafer monitoring systems is described using the plot of FIG. 2.

FIG. 2 illustrates a plot of three pin parameters during the dechucking process of a wafer from a wafer holder over time. Conventional wafer monitoring systems use pin parameters (such as pin torques measured by a torque monitor) to monitor and prevent wafer breakage during the dechucking process. A difficulty encountered by conventional wafer monitoring systems is that wafer breakage events may still occur without indicators in the pin parameters. For example, in the dechucking process illustrated by the plot of FIG. 2, the wafer broke at a break time 202 without an indication the wafer was about to break in any of the three pin parameters plotted.

In an embodiment, the three pin parameters in the plot of FIG. 2 may be parameters measured by the torque monitor 124 while monitoring the pins 108a-c of FIG. 1. Pin parameter labeled as first dataset 210 may be a transfer navigation system (TNS), which may detect absolute wafer movement during processing, or movement of a pin in the wafer holder during the dechucking process over time, such as for any of the pins 108a-c in FIG. 1. Pin parameter labeled as second dataset 220 may be a pin torque of a pin in the wafer holder during the dechucking process over time. And pin parameter labeled as third dataset 230 may be a pin torque delta which is a difference (hence delta) measured between a base value of pin torque prior to the pin contacting the wafer of a pin in the wafer holder during the dechucking process over time.

Still referring to FIG. 2, there was no indication in the pin parameters (210, 220, and 230) the wafer was about to break at break time 202. By including an optical monitoring system, such as by using the light source 110 and the light detector 116 of FIG. 1, the wafer monitoring system of this disclosure may monitor in real-time (via video recording) the dechucking process. And, should a wafer breaking lifting movement indication be detected by the processor 120, the wafer monitoring system 10 of this disclosure may modify pin lifting parameters to prevent the wafer breakage and enable successful dechucking of the wafer 100. The ability of the wafer monitoring systems and methods of this disclosure to monitor in real-time and prevent wafer breakage during dechucking processes is a key benefit of this disclosure over conventional wafer monitoring systems and methods.

One method for determining whether the lifting movement of the wafer during the dechucking process may lead to wafer breakage comprises comparing the real-time video recording to a standard dechucking process, such as the dechucking process illustrated in FIGS. 3A-3C. Significant variation of a real-time monitor of a dechucking process from the standard would cause the wafer monitoring method of this disclosure to modify pin parameters of the wafer holder to prevent wafer breakage.

FIGS. 3A-3C illustrate various points in time of an example lifting movement of a wafer 100 during the dechucking of the wafer 100 from the wafer holder 106 that did not result in wafer breakage. In other words, FIGS. 3A-3C illustrate a standard dechucking process of the wafer 100. The standard dechucking process illustrated in FIGS. 3A-3C may be used as a standard to compare video of subsequent wafer dechuckings to monitor for deviations and modify the dechucking process (or lifting movement) to prevent breaking wafers. Similarly labeled elements may be as previously described.

FIG. 3A illustrates the wafer 100 at the start of a dechucking process. As illustrated in FIG. 3A, wafer 100 still contacts the seal band 104 of the wafer holder 106, and pins 108a-c have not begun to lift the wafer 100 from the wafer holder 106. The dechucking process may begin after the wafer 100 has been processed. For example, this may be a timing configuration in the controller that starts the dechucking of the wafer 100 after processing the wafer for a timeframe.

FIG. 3B illustrates the dechucking process beginning to lift the wafer 100 in a standard lift motion 302 using pins 108a-c. The standard lift motion 302 lifts the wafer 100 at a lift rate. In some embodiments, the lift rate may be a controllable parameter of the pins 108a-c, which may be modified during the lifting movement in order to prevent wafer breakage, or the wafer 100 falling off of the pins 108a-c. In some embodiments, the lift rate is constant. In other embodiments, the lift rate may be accelerated until reaching a maximum lift rate.

FIG. 3C illustrates a last portion of the dechucking process. In FIG. 3C, the wafer 100 has been lifted in the standard lifting motion 302 (in FIG. 3B) by the pins 108a-c to a height (h) above the wafer holder 106. As illustrated, the wafer 100 has been dechucked from the wafer holder 106 and no longer contacts the wafer holder 106 or the seal band 104. The wafer 100 is only supported by pins 108a-c at the height (h) above the wafer holder 106. The wafer monitoring system 10 of FIG. 1, and other embodiment wafer monitoring systems described by this disclosure, may use a video of the standard wafer dechucking process illustrated by FIGS. 3A-3C to compare other wafer dechuckings and take preventative action when deviations are detected to prevent wafer breakage and falling of the wafer. Other embodiments may use light intensities recorded over time, and monitor for variations from the light intensities recorded during standard or control lifting process, such as the dechucking process illustrated and described using FIGS. 3A-3C.

As an example, the processor 120 of FIG. 1 may be used to compare the video being captured by the light detector 116 during a wafer dechucking process to the video of the standard (which may be stored in the memory 122), such as the standard wafer dechucking process illustrated by FIGS. 3A-3C. If significant lifting movement variations are detected between the two recordings, pin parameters controlling the movements of the wafer dechucking process may be modified, such as the lift rate, acceleration, or pressure of the pins. In other embodiments, the processor 120 of FIG. 1 may compare the position of the wafer 100 from the video being recorded by the light detector 116 at different points in time to the standard, and if variation in the lifting movement is detected, take preventative action to avoid wafer breakage. Examples of lifting movements during the dechucking process which may lead to wafer breakage or the wafer falling that the wafer monitoring systems and methods of this disclosure may prevent are described using FIGS. 4A-4C and FIGS. 5A-5C.

FIGS. 4A-4C illustrate various points in time of an example lifting movement which may result in the wafer 100 breaking or falling off of the wafer holder 106 during the dechucking. The lifting movement illustrated in FIGS. 4A-4C may be classified as a slow-motion pop of the wafer 100 from a seal band 404a. Similarly labeled elements may be as previously described.

FIG. 4A illustrates the wafer 100 at the start of a dechucking process. As illustrated in FIG. 4A, wafer 100 still contacts a seal band 404a of the wafer holder 106, and pins 108a-c have not begun to lift the wafer 100 from the wafer holder 106. The dechucking process may begin after the wafer 100 has been processed. As previously described above, this may be a timing configuration in the controller that starts the dechucking of the wafer 100 after processing the wafer for a timeframe.

FIG. 4B illustrates the wafer 100 after the dechucking process has begun and the pins 108a-c start a lift motion 402 of the wafer 100 from the wafer holder 106. In contrast to the embodiment illustrated in FIGS. 3A-3C, a seal band 404b sticks to the wafer 100 as the wafer 100 is lifted from the wafer holder 106 by pins 108a-c. The pins 108a-c continue lifting the wafer 100, but the seal band 404b stretches with the wafer 100 during the lifting until the seal band 404b eventually releases from the wafer 100. As a result, a pop may occur during the separation from the wafer holder 106.

FIG. 4C illustrates a pop 410 as a seal band 404c has released from the wafer 100. The pop 410 (or vibrations) may cause the wafer 100 to break in some embodiments. In other embodiments, the pop 410 (or vibrations) may cause the wafer 100 to vibrate or move off of the pins 108a-c and fall somewhere in the processing chamber, which may also break the wafer 100. As a result, the wafer dechucking process illustrated in FIGS. 4A-4C may cause the wafer 100 to break during the dechucking process. Either scenario may be missed in conventional wafer monitoring that only monitors pin parameters during the dechucking without the real-time optical capabilities of the wafer monitoring systems of this disclosure.

The dechucking process illustrated in FIGS. 4A-4C may be prevented by the wafer monitoring systems and methods of this disclosure. For example, if the wafer 100 is monitored by a real-time optical monitoring system, such as the wafer monitoring system 10 described using FIG. 1, the optical system may be able to monitor for when the seal band 404a-c sticks to the wafer 100 and make a modification to the pin parameters to prevent the pop 410. As a result, the wafer 100 may be successfully dechucked without breaking, which is a benefit of the wafer monitoring systems of this disclosure over conventional systems that only monitor pin parameters during the dechucking process. Another example of lifting movements which may cause wafer breakage or the wafer to fall during the dechucking process that the wafer monitoring systems and method of this disclosure may prevent is illustrated in and described using FIGS. 5A-5C.

FIGS. 5A-5C illustrate various points in time of an example lifting movement which may result in breaking of the wafer 100 during the dechucking. The lifting movement illustrated in FIGS. 5A-5C may be classified as an edge stick of the wafer 100 to the wafer holder 106. Again, similarly labeled elements may be as previously described.

FIG. 5A illustrates the wafer 100 at the start of a dechucking process. As illustrated in FIG. 5A, wafer 100 still contacts the seal band 104 of the wafer holder 106, and pins 108a-c have not begun to lift the wafer 100 from the wafer holder 106. The dechucking process may begin after the wafer 100 has been processed. As previously described above, this may be a timing configuration in the controller that starts the dechucking of the wafer 100 after processing the wafer for a timeframe.

FIG. 5B illustrates the start of the wafer dechucking by lifting the wafer 100 from the wafer holder 106 using pins 108a-c in a lifting motion 502. In lifting motion 502, one side of the wafer 100 sticks to the wafer holder 106 during the dechucking process. As a result, the wafer 100 only lifts on one side and the portion stuck to the wafer holder 106 remains affixed to the wafer holder 106 without lifting with the pins 108a-c. Conventional wafer monitoring systems that only use pin parameters monitoring, such as the plot of FIG. 2, may miss a portion of the wafer 100 remaining stuck to the wafer holder 106 during the lifting motion 502.

As a result of a portion of the wafer 100 sticking to the wafer holder 106 during the lifting motion 502, the wafer 100, once the sticking portion releases, may be ejected in an edge stick motion 504 as illustrated in FIG. 5C. The edge stick motion 504 may result in the wafer 100 being broken during the lifting motion 502, or may result in the wafer 100 falling and subsequently breaking in the processing chamber. Both scenarios may result in the wafer 100 breaking.

The wafer monitoring systems and methods of this disclosure may prevent the edge stick dechucking scenario illustrated in FIGS. 5A-5C. As an example, the edge stick dechucking scenario illustrated in FIGS. 5A-5C would be recognized by the real-time optical monitoring capabilities of the systems and methods of this disclosure. In an embodiment, the light detector 116 may be recording video in real-time that is processed by the processor 120 to prevent wafer breaking scenarios, such as described in FIGS. 4A-4C and FIGS. 5A-5C. Specifically, the wafer monitoring system 10 of FIG. 1 may detect a variation in the lifting motion 502 in FIG. 5B from the standard lifting motion 302 in FIG. 3B. And, after detecting the variation, reverse the lifting motion 502 to have the pins 108a-c return the wafer 100 to the wafer holder 106. After, modifications may be made to the pin parameters by the processor 120 to the instructions stored in the memory 122, such as described above, and the lifting (or dechucking) of the wafer 100 from the wafer holder 106 may be restarted by the controller 118 using the modified instructions in the memory 122. Thus the breaking of the wafer 100 may be avoided and the wafer 100 may be successfully dechucked, which is a benefit of this disclosure over conventional wafer monitoring systems and methods. The change of pin parameters for the dechucking may be forward propagated for future dechucking processes, too.

The wafer monitoring systems and methods of this disclosure may be used to prevent wafer breaking dechucking processes and to optically monitor in real-time dechucking processes after the processing of the wafer has completed. Consequently, both of the two dechucking scenarios which may cause the wafer to break described using FIGS. 4A-4C and FIGS. 5A-5C may be prevented by the wafer monitoring systems and methods of this disclosure. Other dechucking scenarios not illustrated in either FIGS. 4A-4C and FIGS. 5A-5C may also be detected and prevented using the embodiments of this disclosure. In other words, the wafer monitoring systems and methods of this disclosure may be used to prevent more wafer breaking dechucking scenarios than conventional systems and methods. Specifically, because the pin parameters monitored using conventional wafer monitoring systems may present no discernable indication before wafer breakage (such as is illustrated for the break time 202 in FIG. 2), the real-time optical monitoring capabilities of the embodiment systems and methods of this disclosure may be used to prevent more wafer breaking scenarios than conventional systems and methods. Embodiment methods of monitoring a wafer during the dechucking process using the wafer monitoring systems of this disclosure are described using the flowcharts illustrated in FIGS. 6-7.

FIGS. 6-7 illustrate example methods of wafer monitoring using optical devices for real-time variation detection during a dechucking process in accordance with embodiments of this disclosure. The methods of FIGS. 6-7 may be combined with other methods and performed using the systems and apparatuses as described herein, such as the wafer monitoring system 10 illustrated in FIG. 1, and the methods described using FIGS. 3A-3C, FIGS. 4A-4C, and FIGS. 5A-5C. Although shown in a logical order, the arrangement and numbering of the steps of FIGS. 6-7 are not intended to be limited. The method steps of FIGS. 6-7 may be performed in any suitable order.

Referring to FIG. 6, step 610 of a method 600 of monitoring a wafer during a dechucking process illuminates, using a light generated from a light source, a wafer disposed on a wafer holder in a processing chamber. The illumination of the wafer may be performed using a controller coupled to the light source and configured to emit a light at a spectrum comprising a plurality of wavelengths suitable for passing into a processing chamber and illuminating the wafer and wafer holder during a dechucking process. Specifically, the light source is used to illuminate the wafer and wafer holder disposed inside the processing chamber so that the inside of the processing chamber is visible. For example, in an embodiment, the light source may be the light source 110 of FIG. 1 and may emit light in the visible spectrum of wavelengths. Further, in various embodiments, the wafer and wafer holder may be the wafer 100 and the wafer holder 106 illustrated and described in FIG. 1.

Step 620 lifts, using pins disposed in the wafer holder, the wafer. In other words, the lifting of step 620 of the method 600 initializes the dechucking process to remove the wafer from the wafer holder. And in various embodiments, the pins used to lift the wafer from the wafer holder may be the pins 108a-c illustrated in FIG. 1, FIGS. 3A-3C, FIGS. 4A-4C, and FIGS. 5A-5C. Again, the lifting by the pins may be controlled using a controller, such as the controller 118 of FIG. 1.

Still referring to FIG. 6, step 630 of the method 600, during the lifting of step 620, collects a portion of the light at a light detector. For example, step 630 may collect the portion of the light using the light detector 116 described using FIG. 1. Any suitable light detector may be used, such as the various embodiments described for the light detector 116 of FIG. 1. In an embodiment, the light may be continuously collected using a form of camera to capture a video of the lifting process. In other embodiments, the light may be collected by the light detector at specific points in time (taking specific pictures rather than a continuous capture like recording a video). And in further embodiments, the light may be collected by the light detector at specific heights that the wafer is lifted to by the pins over the wafer holder (taking specific pictures rather than a continuous capture like recording a video).

Step 640 of the method 600, based on the collected portion of light captured by the light detector in step 630, determines whether to continue the lifting to complete the dechucking. There are various different embodiment methods for determining whether to continue lifting the wafer, or to restart with modified parameters. The method 600 may prevent wafer breakage with the optimal determination of next steps for the dechucking process. Depending on the determination, the method 600 may stop the lifting, modify a pin parameter of the pins being used to lift the wafer, and then resume the lifting with the modified pin parameters.

In an embodiment, a video being recorded by the light detector may be compared to a standard lifting process or video, such as the standard lifting motion illustrated in FIGS. 3A-3C. If the motion of the wafer during the lifting matches the standard lifting motion stored in memory, then the wafer may proceed with the lifting to complete the dechucking. Other embodiment methods may compare the video to the standard lifting motion and instead detect a variation consistent with the lifting motion 402 of FIG. 4B or the lifting motion 502 of FIG. 5B. As a result, the determination would stop the lifting, lower the wafer back on to the wafer holder, modify the pin parameters, and restart the lifting in step 620. Other embodiment methods that use pictures at specific points in time or pictures at specific heights above the wafer holder may be similarly determined.

Other embodiment methods may use a measurement of the light intensity over time and detect wafer breaking events by detecting variation in light intensity during the dechucking process (lifting). Further, the pin parameters being monitored by some form of pin monitor, such as the torque monitor 124 of FIG. 1, may be used to determine whether to continue the dechucking, too. Embodiment methods and systems that combine both the monitoring of the pin parameters and the real-time optical monitoring using the light detector may be optimal, such as the wafer monitoring system 10 of FIG. 1.

In the embodiments described above for step 640, the determination may be made in the processor, which may make changes to the instructions stored in the memory for the controller to execute. Other embodiments may use a processor that is a part of the controller rather than a separate processor. Another method for monitoring a wafer during a dechucking process is described using FIG. 7 below.

Now referring to FIG. 7, step 710 of a method 700 of monitoring a wafer during a dechucking process has a wafer disposed on a wafer holder of a processing chamber, and illuminates the processing chamber. The illumination of the processing chamber in step 710 may be performed by using the controller 118 coupled to the light source 110 give instructions to the light source 110 to emit a light into the processing chamber 102 of FIG. 1. For example, the light source may be an LED bulb configured to emit a plurality of wavelengths of light in the visible spectrum to illuminate the processing chamber. Step 720 lifts, using pins disposed in the wafer holder, the wafer from the wafer holder to a predetermined distance (or height) above the wafer holder. As described above for the method 600, the pins in step 720 of the method 700 may be pins 108a-c described using FIG. 1, FIGS. 3A-3C, FIGS. 4A-4C, and FIGS. 5A-5C. The lifting motion of the pins may be illustrated by the standard lifting motion 302 of FIG. 3B, or the lifting motions 402 and 502 of FIGS. 4B and 5B, respectively.

Still referring to FIG. 7, step 730, during the lifting of step 720, performs a cyclic process to both monitor and determine actions to be taken during the dechucking process to modify the process or continue without modification until the wafer reaches the predetermined distance above the wafer holder. Each cycle of the cyclic process comprises step 740 and step 750 of the method 700. In step 740, the cyclic process obtains an image corresponding to a location of the wafer during the lifting. In other words, a light detector may be used to capture an image of the illuminated processing chamber during the lifting, such as the light detector 116 of FIG. 1. After, the cyclic process of step 730 proceeds to step 750, and in step 750 the cyclic process performs one of the steps in boxes 752, 754, or 756 based on the image obtained in step 740. If there is no indication in the image that the wafer may break during the dechucking process, box 752 continues the lifting of the wafer. If there is an indication in the image that the wafer may break, but the break may be prevented by simply modifying a parameter of the lifting (such as a pin parameter of the pins), box 754 modifies a parameter of the lifting. And if there is an indication in the image that the wafer may break, but the break may be prevented by restarting the dechucking process, box 756 lowers the wafer back on to the wafer holder to restart the lifting of the wafer. Further, box 756 may also modify a parameter of the lifting before restarting the process.

Once one of the steps in boxes 752, 754, or 756 have been taken, the cyclic process may resume in step 740 until the wafer has been lifted to the predetermined distance above the wafer holder. In an embodiment, the predetermined distance above the wafer holder of step 720 may be the height (h) illustrated in FIG. 3C. As described above, the various steps of the method 700 may be performed using the wafer monitoring systems described in this disclosure, such as the wafer monitoring system 10 of FIG. 1.

The wafer monitoring systems and method of this disclosure are capable of recognizing and ameliorating wafer breaking phenomena before they occur during a dechucking process. Further, the wafer monitoring systems and methods described throughout this disclosure may also include pin parameter monitoring, too. As a result, the wafer monitoring systems and methods of this disclosure may monitor in real-time using the optical capabilities of the systems combined with the other forms of wafer lifting motions which are detectable by the pin parameter monitoring of conventional systems and methods to optimize the prevention of wafer breakage during dechucking. Further, the systems and methods of this disclosure, by reducing the number of wafer breaking dechucking processes, may also increase fabrication throughput and efficiency.

Example embodiments of the invention are described below. Other embodiments can also be understood from the entirety of the specification as well as the claims filed herein.

Example 1. A method for monitoring a dechucking of a wafer includes illuminating, using light generated from a light source, the wafer disposed on a wafer holder in a processing chamber. The method further includes lifting, using pins disposed in the wafer holder, the wafer, and during the lifting, collecting a portion of the light at a light detector. And the method further includes, based on the collected portion of the light, determining whether to continue the lifting to complete the dechucking.

Example 2. The method of example 1, where based on the collected portion of the light, determining to continue the lifting and completing the dechucking.

Example 3. The method of one of examples 1 or 2, where based on the collected portion of the light, stopping the lifting and performing an interrupt process, the interrupt process including generating a control signal to modify the lifting, and continuing the lifting to complete the dechucking after modifying the lifting.

Example 4. The method of one of examples 1 to 3, where modifying the lifting includes using a processor to overwrite instructions in a memory with a modified lift rate for the pins.

Example 5. The method of one of examples 1 to 4, where based on the collected portion of the light, stopping the lifting and performing an interrupt process, the interrupt process including generating a control signal to lower the wafer back on to the wafer holder, modify the lifting, and restarting the lifting to complete the dechucking after modifying and restarting the lifting.

Example 6. The method of one of examples 1 to 5, where determining whether to continue the lifting to complete the dechucking includes determining a classification of lifting movement of the wafer by comparing the collected portion of the light to a reference light.

Example 7. The method of one of examples 1 to 6, where determining the classification of lifting movement includes comparing the collected portion of the light to the reference light to determine a variation, and based on the variation, determining the classification of lifting movement.

Example 8. The method of one of examples 1 to 7, where the classification of lifting movement is the wafer lifted from the wafer holder without sticking. Or where the classification of lifting movement is a slow motion pop, the slow motion pop being the classification of lifting movement for when a seal band of the wafer holder sticks to an outer edge of the wafer and lifts with the wafer. Or where the classification of lifting movement is a partial edge stick, the partial edge stick being the classification of lifting movement for when a portion of an outer edge of the wafer sticks to the wafer holder during the lifting.

Example 9. A method for monitoring a dechucking of a wafer includes having the wafer disposed on a wafer holder of a processing chamber, and illuminating the processing chamber. And the method further includes lifting, using pins disposed in the wafer holder, the wafer from the wafer holder to a predetermined distance above the wafer holder, and during the lifting performing a cyclic process. One cycle of the cyclic process includes obtaining an image corresponding to a location of the wafer during the lifting. One cycle of the cyclic process further includes, based on the image, performing one of the following steps: continuing the lifting of the wafer, modifying a parameter of the lifting, or lowering the wafer back on to the wafer holder to restart the lifting of the wafer.

Example 10. The method of example 9, where cycles of the cyclic process are performed at predefined time intervals.

Example 11. The method of one of examples 9 or 10, where cycles of the cyclic process are performed at predefined distances from the wafer to the wafer holder.

Example 12. The method of one of examples 9 to 11, where based on the image, performing one of the following steps includes comparing the image to a reference image to determine the step to be performed, or comparing the image to a reference image and monitoring the parameter of the lifting to determine the step to be performed, or comparing light intensities of the image to reference light intensities of a reference image to determine the step to be performed.

Example 13. The method of one of examples 9 to 12, where continuing the lifting of the wafer includes continuing to lift the wafer from the wafer holder using the pins without modifying the parameter of the lifting.

Example 14. The method of one of examples 9 to 13, where modifying the parameter of the lifting includes rewriting a memory of a controller operating the lifting.

Example 15. The method of one of examples 9 to 14, where lowering the wafer back on to the wafer holder to restart the lifting of the wafer includes rewriting a memory of a controller operating the lifting to cause the controller to lower the pins of the wafer holder until the wafer contacts the wafer holder and then restarts the lifting using the pins.

Example 16. The method of one of examples 9 to 15, where the parameter of the lifting includes a lift rate of the pins of the wafer holder.

Example 17. A system for monitoring a dechucking of a wafer includes a wafer holder disposed in a processing chamber, the wafer holder including pins. The system further includes a light source optically coupled to the processing chamber, and a light detector optically coupled to the processing chamber. And the system further includes a processor coupled to the light detector, a memory, and a controller, the controller coupled to the light detector, the pins, the light source, and the memory storing instructions to be executed in the controller. The instructions when executed cause the controller to illuminate, using light generated from the light source, the wafer disposed on the wafer holder in the processing chamber. The instructions when executed further cause the controller to lift, using the pins disposed in the wafer holder, the wafer, and during the lifting, collect a portion of the light at the light detector. And the instructions when executed further cause the controller to, based on the collected portion of the light, determine whether to continue the lifting to complete the dechucking using the processor.

Example 18. The system of example 17, where the wafer holder includes an electrostatic chuck, the light source includes an LED bulb, the light detector includes a video camera, the wafer includes a silicon wafer, and the processor includes a computer.

Example 19. The system of one of examples 17 or 18, where the light source optically couples to the processing chamber through an incident window disposed on a sidewall of the processing chamber, and the light detector optically couples to the processing chamber through a collection window disposed on the sidewall of the processing chamber opposite the incident window.

Example 20. The system of one of examples 17 to 19, further including a torque monitor coupled to the pins of the wafer holder to monitor parameters of the lift.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for monitoring a dechucking of a wafer, the method comprising:
illuminating, using light generated from a light source, the wafer disposed on a wafer holder in a processing chamber;
lifting, using pins disposed in the wafer holder, the wafer;
during the lifting, collecting a portion of the light at a light detector; and
based on the collected portion of the light, determining whether to continue the lifting to complete the dechucking.

2. The method of claim 1, wherein based on the collected portion of the light, determining to continue the lifting and completing the dechucking.

3. The method of claim 1, wherein based on the collected portion of the light, stopping the lifting and performing an interrupt process, the interrupt process comprising generating a control signal to modify the lifting, and continuing the lifting to complete the dechucking after modifying the lifting.

4. The method of claim 3, wherein modifying the lifting comprises using a processor to overwrite instructions in a memory with a modified lift rate for the pins.

5. The method of claim 1, wherein based on the collected portion of the light, stopping the lifting and performing an interrupt process, the interrupt process comprising generating a control signal to lower the wafer back on to the wafer holder, modify the lifting, and restarting the lifting to complete the dechucking after modifying and restarting the lifting.

6. The method of claim 1, wherein determining whether to continue the lifting to complete the dechucking comprises determining a classification of lifting movement of the wafer by comparing the collected portion of the light to a reference light.

7. The method of claim 6, wherein determining the classification of lifting movement comprises:
comparing the collected portion of the light to the reference light to determine a variation; and
based on the variation, determining the classification of lifting movement.

8. The method of claim 7, wherein the classification of lifting movement is the wafer lifted from the wafer holder without sticking; a slow motion pop, the slow motion pop being the classification of lifting movement for when a seal band of the wafer holder sticks to an outer edge of the wafer and lifts with the wafer; or a partial edge stick, the partial edge stick being the classification of lifting movement for when a portion of an outer edge of the wafer sticks to the wafer holder during the lifting.

9. A method for monitoring a dechucking of a wafer, the method comprising:
having the wafer disposed on a wafer holder of a processing chamber, and illuminating the processing chamber; and
lifting, using pins disposed in the wafer holder, the wafer from the wafer holder to a predetermined distance above the wafer holder, during the lifting performing a cyclic process, one cycle of the cyclic process comprising:
obtaining an image corresponding to a location of the wafer during the lifting,
based on the image, performing one of the following steps:
continuing the lifting of the wafer, or
modifying a parameter of the lifting, or
lowering the wafer back on to the wafer holder to restart the lifting of the wafer.

10. The method of claim 9, wherein cycles of the cyclic process are performed at predefined time intervals.

11. The method of claim 9, wherein cycles of the cyclic process are performed at predefined distances from the wafer to the wafer holder.

12. The method of claim 9, wherein based on the image, performing one of the following steps comprises:
comparing the image to a reference image to determine the step to be performed;
comparing the image to a reference image and monitoring the parameter of the lifting to determine the step to be performed; or
comparing light intensities of the image to reference light intensities of a reference image to determine the step to be performed.

13. The method of claim 9, wherein continuing the lifting of the wafer comprises continuing to lift the wafer from the wafer holder using the pins without modifying the parameter of the lifting.

14. The method of claim 9, wherein modifying the parameter of the lifting comprises rewriting a memory of a controller operating the lifting.

15. The method of claim 9, wherein lowering the wafer back on to the wafer holder to restart the lifting of the wafer comprises rewriting a memory of a controller operating the lifting to cause the controller to lower the pins of the wafer holder until the wafer contacts the wafer holder and then restarts the lifting using the pins.

16. The method of claim 9, wherein the parameter of the lifting comprises a lift rate of the pins of the wafer holder.

17. A system for monitoring a dechucking of a wafer, the system comprising:
a wafer holder disposed in a processing chamber, the wafer holder comprising pins;
a light source optically coupled to the processing chamber;
a light detector optically coupled to the processing chamber; and
a processor coupled to the light detector, a memory, and a controller, the controller coupled to the light detector, the pins, the light source, and the memory storing instructions to be executed in the controller, the instructions when executed cause the controller to:
illuminate, using light generated from the light source, the wafer disposed on the wafer holder in the processing chamber,
lift, using the pins disposed in the wafer holder, the wafer,
during the lifting, collect a portion of the light at the light detector, and
based on the collected portion of the light, determine whether to continue the lifting to complete the dechucking using the processor.

18. The system of claim 17, wherein the wafer holder comprises an electrostatic chuck, the light source comprises an LED bulb, the light detector comprises a video camera, the wafer comprises a silicon wafer, and the processor comprises a computer.

19. The system of claim 17, wherein
the light source optically couples to the processing chamber through an incident window disposed on a sidewall of the processing chamber, and
the light detector optically couples to the processing chamber through a collection window disposed on the sidewall of the processing chamber opposite the incident window.

20. The system of claim 17, further comprising a torque monitor coupled to the pins of the wafer holder to monitor parameters of the lift.
